(19) United States
(12) Patent Application Publication
(10) Pub. No.: US 2020/0056302 A1
(43) Pub. Date: Feb. 20, 2020

(54) Elimination of Basal Plane Dislocation and Pinning the Conversion Point Below the Epilayer Interface for SiC Power Device Applications

(71) Applicant: UNIVERSITY OF SOUTH CAROLINA, COLUMBIA, SC (US)

(72) Inventors: ANUSHA BALACHANDRAN, COLUMBIA, SC (US); MVS CHANDRASHEKHAR, COLUMBIA, SC (US); TANGALI S. SUDARSHAN, COLUMBIA, SC (US)

(21) Appl. No.: 16/487,287

(22) PCT Filed: Mar. 1, 2018
(86) PCT No.: PCT/US2018/020362

§ 371 Date: Aug. 20, 2019

Related U.S. Application Data
(60) Provisional application No. 62/465,925, filed on Mar. 2, 2017.

(51) Int. Cl. C30B 25/18; C30B 29/36; C30B 25/20; H01L 21/02

(52) U.S. Cl. CPC C30B 25/183; C30B 29/36; C30B 25/20; H01L 21/0262; H01L 21/02447; H01L 21/02529; H01L 21/02609; H01L 21/02378

(57) ABSTRACT

Methods are provided for growing basal plane dislocation (BPD)-free SiC device-ready epilayers, particularly suitable for 4H-SiC devices. The devices are formed via a substantially 100% conversion of BPDs to threading edge dislocations (TEDs) while pinning the conversion point below the epilayer interface. Methods include the formation of a recombination layer on a previously formed and etched buffer layer. Devices allow for improved reliability and efficiency of high voltage switches used in the day-to-day applications such as inverters, uninterrupted power supplies, and other high power handling devices employed in hybrid electric vehicles, aircraft electronic systems, etc. by enabling the manufacture of smaller, lighter, and more efficient, high power SiC devices in a cost effective, reliable platform.

### CROSS REFERENCE TO RELATED APPLICATION

This application claims filing benefit of U.S. Provisional Patent Application Ser. No. 62/465,925, having a filing date of Mar. 2, 2017, which is incorporated herein by reference for all purposes.

### GOVERNMENT SUPPORT CLAUSE

This invention was made with government support under 1309466 awarded by the National Science Foundation. The government has certain rights in the invention.

### BACKGROUND

Power electronic semiconductor devices are critical components in next-generation energy-efficient power systems such as electric vehicles, smart grid power controls, and alternative energy grid-compatibility circuitry. Their power handling capabilities and ability to operate at high temperatures without active cooling enables transformative system-level improvements such as reduction in size, weight, and performance. Wide bandgap materials such as silicon carbide (SiC), gallium nitride (GaN), and diamond have been investigated to replace the industry workhorse, with silicon materials particularly suitable due to their superior material properties.¹ Of these materials, 4H—SiC is considered the most viable candidate beyond 3 kV due to its technological maturity, owing to the wide band gap (3.26 eV), high breakdown field and more importantly, its indirect bandgap. This gives it much longer minority carrier recombination lifetimes of microseconds vs. nanoseconds for direct bandgap materials such as GaN, making it the only practical wide-bandgap for bipolar devices that require long carrier lifetimes for high current handling. Translating these material advantages into real devices requires high quality SiC with low density of defects, particularly basal plane dislocations (BPDs).

4H—SiC homoepitaxy on off-oriented substrates is the key to fabricating reliable SiC bipolar power devices. High gain 4H—SiC bipolar junction transistor (BJT) devices have potential applications in high power switching.³ However, off-oriented substrates suffer from a major drawback of producing device killing crystal defects such as Basal Plane Dislocations (BPDs) on the grown epilayers which nucleate into Shockley-type stacking faults (SF) under bipolar forward bias conditions and deteriorate the device performance characteristics by limiting minority carrier concentration and causing forward voltage drifts.⁴

As mentioned, offoriented substrates generate BPDs on the epilayers due to the tilt in their basal plane (0001, c-axis). BPDs are dislocations that can glide along the basal (0001) plane of the growing crystal. About 70-90% of BPDs in the off oriented substrate spontaneously convert to threading edge dislocations (TEDs) at the epilayer/substrate interface⁵ or during the growth throughout the epilayer thickness⁶ with the conversion efficiency depending upon growth conditions.⁷ However, a fraction of the substrate BPDs propagates into the active layers of devices where they are detrimental to device performance, and are currently considered the yield-limiting killer defect in SiC power devices⁴.

As explained by Klapper and Kiipper⁸, BPD to TED conversion occurs according to equation (1):

W=E/cos α (1)

where, W is the elastic energy of the dislocation per unit growth length, E is the elastic energy per unit length of dislocation line, a is the angle between the dislocation line and the growth direction, i.e., α=90-offcut angle θ, as shown in FIG. 1.

With a reduction in the offcut angle, W_{BPD} increases while W_{TED} reduces. The elastic energy per unit length of dislocation line for BPDs and TEDs was found to be almost the same, (i.e., E_{BPD}˜E_{TED}⁹) and we get W_{BPD}>>W_{TED}. Hence, it is energetically favorable for a BPD to get converted into a TED during epitaxial growth on a low offcut substrate.¹⁰ It has been shown that growing on low-offcut substrates significantly enhances BPD conversion.¹¹ However, as one approaches close to on-axis<1°, the possibility of 3C inclusions increases, along with the possibility of step flow from the <1100> unintentional miscut direction leading to degradation of surface morphology.¹⁰

Various successful approaches to increasing the conversion efficiency have been reported including the modification of growth conditions such as:

i) Substrate pretreatment (etching) using molten potassium hydroxide (KOH),^{6,12} or using molten eutectic mixture (Na0H+KOH);¹³

ii) High temperature annealing of the substrates before growth;^{14,15}

iii) In situ hydrogen etching before epitaxy;¹⁶

iv) In situ growth interrupts.¹⁷

One common factor in all of the above-mentioned processes is pretreatment of the substrates before epitaxial growth. Since the BPD density is high—ranging from 500 cm⁻² to 800 cm⁻² in a 100 mm substrate¹⁸—it is difficult to produce 100% conversion at the substrate/epilayer interface. BPD conversion at the substrate/epilayer interface is very important for high reliability of SiC power devices as the BPDs buried in the epilayer can still be converted to SFs under current stress, and these SFs will extend to the device active layer and degrade the device performance¹⁹. Taking into account that 500 BPDs/cm² are on the substrate surface and 99% of them are converted to TEDs^{20,21,22} producing ˜5 BPDs/cm² on the epilayer surface, it is still a significant value adversely affecting the epitaxial wafer yield for device fabrication. Thus, 100% conversion at the substrate/epilayer interface for 4° off oriented substrates is essential to achieve high yield and performance characteristics of SiC devices at the commercial level.

Earlier studies conducted by V. D.Wheeler et al.⁴ have shown that BPD conversion on the epilayer show abrupt increase on low doped nitrogen films (<10¹⁶ cm⁻³) while high doped films show minimal BPD conversion. Recently, Song and Sudarshan²² developed a “growth-etch-regrowth” technique which employs a well-controlled eutectic etching method to achieve a BPD-free epilayer with almost no surface degradation for 8° SiC epilayers. The etch pits are created when the eutectic chemical etchants (KOH—NaOH—MgO salt mixture) react with the SiC epilayer and selectively (anisotropically) etch the areas where the crystal defects are present²³. Large etch pits are easier to obtain on low doped epilayers than on the high doped epilayers for the same etching conditions. This is due to the influence of high nitrogen concentration on the high-doped epilayers hindering the etching process.²³ Zhang and Sudarshan⁵ demonstrated that the lateral growth on the etch pits forces the BPDs to convert into TEDs, which implies that the narrower the BPD etch pit, the easier it is for the lateral growth to force BPD conversion into TEDs within a thinner layer. This makes eutectic etching on low-doped epilayers a highly preferable method for BPD conversion and growing the active device epilayer on a low-doped buffer layer is one way to mitigate BPDs in the device layer.

Typically, high-doped epilayers (˜10¹⁸ cm⁻³) are used as buffer layers due to their low on-resistance and suitability as effective recombination layers; however, they are not conducive for 100% BPD conversion.⁴ On the other hand, using a low-doped buffer layer, while good for BPD conversion, was thought to introduce unacceptably high on-resistance, since >10 μm thick buffer layers are required.⁴ However, with improvements in buffer layer growth, layers as thin as 1.5 μm¹³ are possible to achieve 100% BPD conversion, giving a 10× improvement in on-resistance.

However, recombination rates, R, in low-doped buffer layers are much smaller than in high-doped buffer layers since R∝Nd²⁴. The low doping density in the buffer layer, with corresponding diffusion lengths >10 μm²⁵, means that for low-doped buffer layers, even if they are >10 μm thick, recombination can still occur at the buffer layer/SiC substrate interface, where BPDs are still present causing stacking fault nucleation under bipolar current injection. These stacking faults can expand into the buffer layer, and eventually into the active device layer, rendering the original BPD-free buffer layer ineffective. Thus, low-doped buffer layers, even if they are grown thicker may not prevent stacking fault nucleation.

Therefore, conversion of BPD to TED near the epilayer/substrate interface without degrading the surface morphology is an important need for the reliability of SiC devices. Though 100% BPD to TED conversion has been achieved previously, the conversion occurs at the epilayer/substrate interface⁸ or lies close to the interface (˜2 μm)⁹ where a segment of BPD(s) is still in the active layer of the device. At high current stress, these segments can undergo stacking fault nucleation during minority carrier recombination thereby degrading the device performance¹⁸. This has been a challenge in the SiC epitaxial growth. Thus, converting the BPDs to TEDs below the epilayer interface is necessary to achieve reliable commercial quality SiC epilayers for high power devices (e.g. BJTs, PIN diodes, Schottky diodes).

### SUMMARY

According to one embodiment, disclosed is a method for growing a composite SiC epilayer structure. For instance, a method can include growing a buffer layer on a surface of a SiC substrate, the buffer layer comprising SiC. A method can also include applying a molten mixture directly to the buffer layer and thereby forming a treated buffer layer. Thereafter, a method can include growing a recombination layer on the treated buffer layer. The recombination layer including SiC.

### BRIEF DESCRIPTION OF THE FIGURES

A full and enabling disclosure of the present subject matter, including the best mode thereof to one of ordinary skill in the art, is set forth more particularly in the remainder of the specification, including reference to the accompanying figures in which:

FIG. 1 illustrates a BPD with dislocation line parallel to the [11-20] off-cut direction.

FIG. 2 is a schematic of a 4H—SiC device template for fabricating P-i-N diodes or BJTs with specific on-resistance, Rₒₙ₋ₛₚ (total) (recombination+buffer epilayers)=0.47 mΩ-cm².

FIG. 3 schematically illustrates a formation and investigation method described further herein.

FIG. 4A graphically presents a buffer epilayer theoretical series on resistance with regard to net doping concentration vs. net doping concentration.

FIG. 4B graphically presents a buffer epilayer theoretical series BPD and IGSF densities vs. net doping concentration.

FIG. 5A is a Nomarski image of the defects seen after eutectic etching of a first buffer epilayer grown at a C/Si ratio of 1.42 for 15 minutes growth duration.

FIG. 5B is another Nomarski image of the defects seen after eutectic etching of a first buffer epilayer grown at a C/Si ratio of 1.42 for 15 minutes growth duration.

FIG. 5C is another Nomarski image of the defects seen after eutectic etching of a first buffer epilayer grown at a C/Si ratio of 1.42 for 15 minutes growth duration.

FIG. 5D is a Nomarski image of the defects seen after eutectic etching of a first buffer epilayer grown at a C/Si ratio of 1.42 for 15 minutes growth duration.

FIG. 6A is a typical AFM image of BPDs seen on buffer epilayers.

FIG. 6B schematically illustrates the influence of large sector and narrow sector opening of BPD etch pits for propagation and conversion.

FIG. 7A graphically illustrates recombination layer thickness and net doping concentration with regard to C/Si ratio (trend lines shown are guide to the eyes).

FIG. 7B graphically illustrates BPD and IGSF density with regard to net doping concentration.

FIG. 8A is an NOM image taken after KOH etching of converted BPDs to TEDs seen on a recombination layer at the corresponding buffer epilayer positions formed with a C/Si ratio of 0.6.

FIG. 8B is an NOM image taken after KOH etching of converted BPDs to TEDs seen on a recombination layer at the corresponding buffer epilayer positions formed with a C/Si ratio of 1.0.

FIG. 8C is an NOM image taken after KOH etching of converted BPDs to TEDs seen on a recombination layer at the corresponding buffer epilayer positions formed with a C/Si ratio of 1.42.

FIG. 8D is an NOM image taken after KOH etching of converted BPDs to TEDs seen on a recombination layer at the corresponding buffer epilayer positions formed with a C/Si ratio of 1.8.

FIG. 9 graphically illustrates net BPD to TED conversion ratio from buffer to recombination layer with regard to C/Si ratios

FIG. 10 schematically illustrates the BPD-TED conversion point shift at C/Si=1.0

FIG. 11 schematically illustrates composite growth structure as described herein.

FIG. 12A is an optical microscopy image of a buffer epilayer showing a BPD etch pit after eutectic etching as described in the Examples section herein.

FIG. 12B is an optical microscopy image of a recombination layer showing the shift in the conversion of BPD to TED as described in the Examples section herein.

FIG. 13 is an atomic force microscope (AFM) image of recombination layer at C/Si=1.0 showing step flow growth.

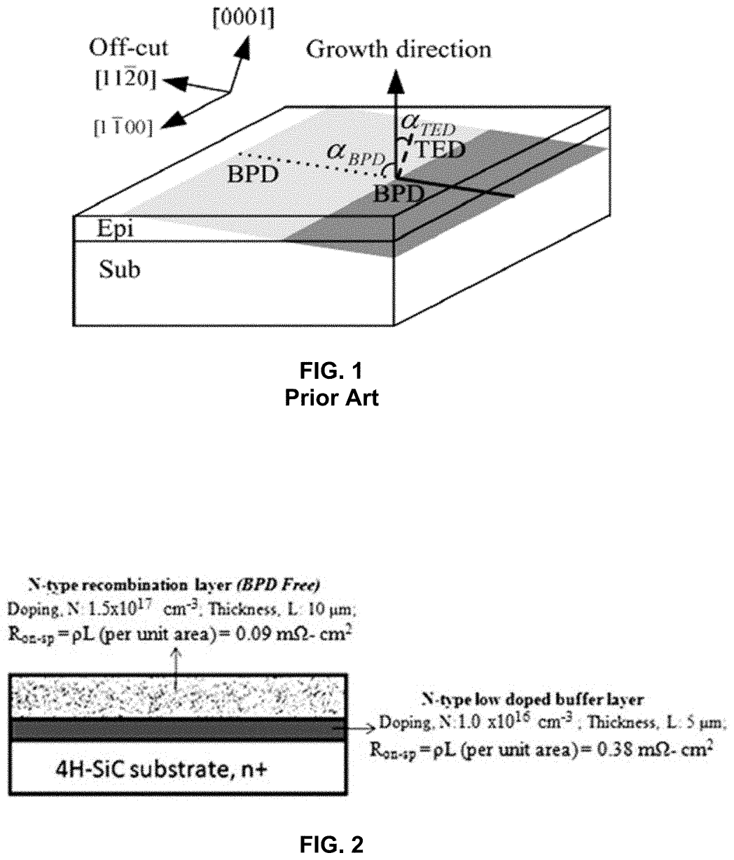

Repeat use of reference characters in the present specification and drawings is intended to represent the same or analogous features or elements of the present invention.

### DETAILED DESCRIPTION

The following description and other modifications and variations to the present invention may be practiced by those of ordinary skill in the art, without departing from the spirit and scope of the present invention. In addition, it should be understood that aspects of the various embodiments may be interchanged both in whole or in part. Furthermore, those of ordinary skill in the art will appreciate that the following description is by way of example only and is not intended to limit the invention.

In the present disclosure, when a layer is being described as “on” or “over” another layer or substrate, it is to be understood that the layers can either be directly contacting each other or have another layer or feature between the layers, unless expressly stated to the contrary. Thus, these terms are simply describing the relative position of the layers to each other and do not necessarily mean “on top of” since the relative position above or below depends upon the orientation of the viewer or the specific application for device fabrication.

Chemical elements are discussed in the present disclosure using their common chemical abbreviation, such as commonly found on a periodic table of elements. For example, hydrogen is represented by its common chemical abbreviation H; helium is represented by its common chemical abbreviation He; and so forth.

Various methods are generally provided for reducing and even eliminating basal plane dislocation density in SiC epilayers grown using hotwall CVD processes on a SiC substrate in order to achieve high quality epitaxy. For example, each of these process steps can be utilized alone, or in combination with each other, to achieve high quality epitaxial growth. It is noted that terms “epitaxial film” and “epilayer” are used interchangeably in the present disclosure.

Methods are generally provided for growing BPD-free SiC device-ready epilayers, particularly suitable for 4H—SiC devices, that are formed via a substantially 100% conversion of BPDs to threading edge dislocations (TEDs) while pinning the conversion point below the epilayer interface. Devices made according to these methods allow for improved reliability and efficiency of high voltage switches used in the day-to-day applications such as inverters, uninterrupted power supplies, and other high power handling devices employed in hybrid electric vehicles, aircraft electronic systems, etc. by enabling the manufacture of smaller, lighter, and more efficient, high power SiC devices in a cost effective, reliable platform. This development is achieved by improving the quality of the semiconductor material (e.g., 4H—SiC) through the methods described herein.

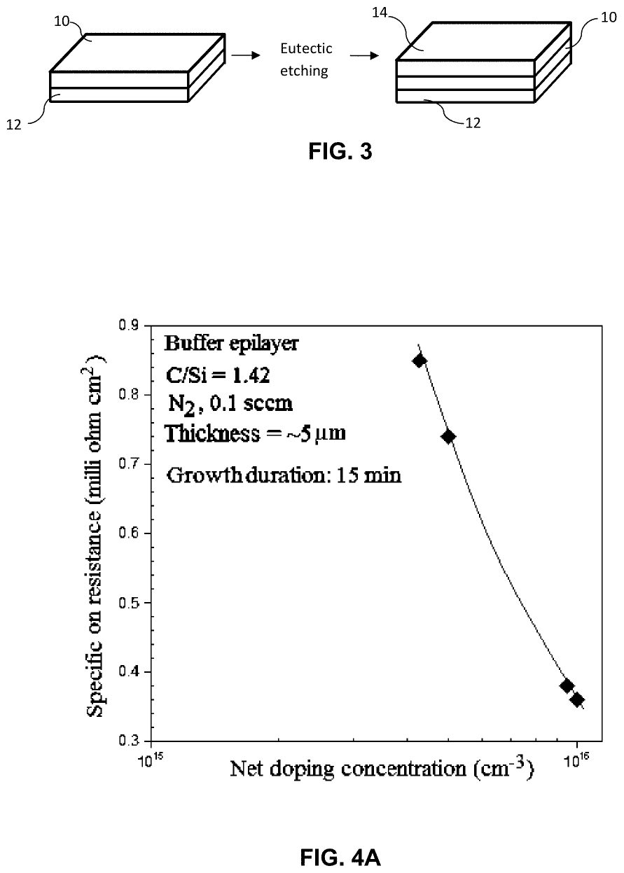

In one embodiment, and as illustrated in FIG. 3, a method can begin with growing a thin low-doped buffer layer 10 on a SiC substrate 12 via a CVD process as is known in the art, e.g., a hotwall CVD process. The substrate can be any suitable SiC substrate. In some embodiments, the SiC substrate can be a polytype of SiC selected from the 3C, 4H, 6H, or 15R. The SiC substrate can have an offcut angle ranging from 0.5° to 12°, such as an offset angle of about 1°, 2°, 4°, 6°, 8°, 10°, or 12°. The SiC substrate can have a doping concentration selected from N+, N−, P+, P− and semi-insulating.

The buffer layer 10 can be relatively thin and can generally have a dopant concentration ranging from semi-insulating to less than about 10¹⁷ cm⁻³, such as about 5×10¹⁵ cm⁻³ to about 1'10¹⁶ cm⁻³, N-type. A buffer layer 10 may be, for example, about 0.5 μm to about 5 μm thick (e.g., about 1.5 μm to about 5 μm), which can reduce the total device series on-resistance significantly when compared to a device with a thicker buffer layer.

Following formation, the buffer layer 10 may then be etched to convert substantially all of the BPDs to TEDs (e.g., 100% BPD conversion), such as by using a molten eutectic mixture including KOH and/or a buffering agent (e.g., MgO, GaO, or mixtures thereof) as described in U.S. Pat. No. 8,900,979, which is incorporated herein by reference in its entirety. For instance, the mixture can include KOH and a buffering agent, with the buffering agent present in the mixture in an amount of about 5% to about 80% by weight of the mixture, for instance about 5% to about 20% by weight of the mixture. In one embodiment, a eutectic mixture for etching a surface can include an additional salt such as, without limitation, NaOH, KNO₃, Na₂O₂, or a mixture thereof. For instance, an additional salt can be present in the mixture in an amount such that the weight ratio of KOH to the salt (e.g., NaOH) is from about 1:4 to about 4:1. In one embodiment, the eutectic mixture can include KNO₃, for instance in an amount such that the weight ratio of KOH to KNO₃ is from about 1:20 to about 5:1. In general, the etching mixture can be applied as a molten mixture at a temperature of from about 170° C. to about 800° C., for instance as a suspension of a buffering agent in the form of a fine powder dispersed in a molten KOH-based liquid. The etching treatment time can generally vary from about 1 minute to about 60 minutes.

After formation and etching of the buffer layer, a recombination layer 14 is formed thereon, generally, though not necessarily, by the same formation process as was used to form the buffer layer, e.g., a hotwall CVD process. The inclusion of the recombination layer 14 can ensure that all recombination occurs within a BPD-free region.

In general, the recombination layer 14 has a higher doping concentration than the buffer layer 10. In one embodiment, a higher-doped recombination layer 14 may be moderately thick (e.g., thicker than the buffer layer 10), such as about 5 μm or greater, or about 10 μm or greater. In some embodiments, a recombination layer 14 can have a thickness of about 10 μm to about 25 μm, which can ensure that all of the minority carrier recombination occurs within this highly-doped recombination layer 14.

A recombination layer 14 can have a higher concentration of dopant than the buffer layer, such as about 1×10¹⁶ cm⁻³ or greater (e.g., about 10¹⁷ cm⁻³ or greater), N-type. In one particular embodiment, a recombination layer 14 can have a dopant concentration of about 5×10¹⁶ cm⁻³ to about 1.6×10¹⁷ cm⁻³, N-type. High doping of the BPD-free recombination layer 14 can ensure fast carrier recombination under forward bias, preventing any stacking fault nucleation in the active layer during bipolar device operation. Beneficially, all individual BPDs in the buffer epilayer 10 can be converted at the interface of the buffer/recombination layers to benign TEDs over a wide range of C/Si ratios for the recombination layer, introducing a minimal on-resistance of <0.5 mΩ/cm². By way of example, a recombination layer 14 can have a C/Si ratio of about 0.5 to about 2, for instance 0.6 to about 1.8, or about 1 to about 1.8 in some embodiments. 100% BPD conversion can occur due to the controlled and highly anisotropic eutectic etching of the buffer layer which produces narrow sector angle (5°) for the BPD etch pits to enable conversion of the BPDs into TEDs, by promoting lateral growth at the narrow sector of BPD etch pits.

Without wishing to be bound by any particular theory, it is believed that a shift in the BPD to TED conversion point for the recombination layer growth occurs at a carbon to silicon ratio (C/Si ratio) of about 0.6 to about 1.4 (e.g., about 0.8 to about 1.2), as determined by molar ratio. In one particular embodiment, the C/Si ratio can be about 0.95 to about 1.05, such as about 0.99 to about 1.01. For example, the C/Si ratio may be 1 in some embodiments. As such, the dislocation can be pushed below the buffer layer/recombination layer interface, thereby increasing the threshold to withstand high forward current stress at high voltage conditions. This result can enable the translation of BPD conversion technology to real high power bipolar or unipolar device architectures in applications such as electric vehicles and solar power grid compatibility circuitry.

Through engineering of the thicknesses and doping of these two layers (i.e., the buffer layer 10 and the recombination layer 14), these layers will not introduce a significant addition to the on-resistance of the device, while enabling translation of BPD conversion technology into real devices. In other words, growing an active device recombination epilayer 14 on a low doped buffer layer 20 can be non-detrimental to the device specific on-resistance while greatly advantageous for enhancing 100% BPD conversion.

The creation of BPD-free recombination layer with high doping is a significant technological improvement in the field of SiC epitaxy for producing robust, forward voltage drift free bipolar devices.

The present disclosure may be better understood by reference to the Examples, set forth below.

### EXAMPLES

A 4H—SiC BJT power device reported by Cree Inc.³ has a series on-resistance of 10.8 mΩ-cm². Since the 4H—SiC mobility is highly dependent on the free carrier concentration (˜815 cm2V⁻¹s⁻¹ for ˜10¹⁶ cm⁻³ and drops to 250 cm²V⁻¹s⁻¹ for 1018 cm−3),²⁶ low-doped buffer layers (n=1×10¹⁶ cm⁻³, mobility μ˜815 cm²V⁻¹s⁻¹) with epilayer thickness (L) as low as 1.5 μm will add a specific on-resistance of only 0.12 mΩ-cm² to the device, or 1%. This was calculated using the formula (2):

Specific on-resistance, Rₒₙ₋ₛₚ=ρL per unit area=L/nqμ per unit area (Ω-cm²) (2)

For the buffer/recombination layer demonstrated in this Example (schematically illustrated in FIG. 2), the total addition was <0.5 mΩ-cm², or <5%. This may be further reduced with optimization of the growth process, although 5% is within reasonable engineering tolerances for the thickness and doping, which will eventually determine the device variability. Moreover, the fact that for a typical recombination layer doping at 2×10¹⁷cm⁻³, the mobility has already decreased from ˜900 cm²/Vs 26 to <250 cm²/Vs²⁶ shows that the recombination (R) has been greatly enhanced by the larger number of dopants through impurity scattering. In addition, R is enhanced, by the larger number of carriers. (n), as expected from the continuity equations²⁰:

R=βnp (3)

where, R=recombination rate (cm⁻³ s⁻¹), n and p=carrier densities of electrons and holes (cm⁻³), β=proportionality constant.

With this in mind, in these Examples, for the first time 100% conversion of BPDs is reported on higher doped (recombination) epilayers (5×10¹⁶cm⁻³ to 1.6×10¹⁷ cm⁻³) by first growing a low n-doped (5×10¹⁵cm⁻³ to 1×10¹⁶ cm⁻³) buffer epilayer on a 4° off 4H—SiC n+ substrate, and then mildly etching the buffer layer by a modified eutectic mixture (MgO+NaOH+KOH). The etched buffer epilayer with exposed etch pits (˜5 μm to 7 μm) were then subjected to growth of a recombination layer at high doping concentration under different C/Si ratios (from 0.6 to 1.8), and the underlying BPD to TED conversion mechanism from the buffer epilayer to the recombination layer were studied in detail. Growth condition to produce BPD free epilayers with minimum in-grown stacking fault (IGSF) density is reported.

### Example 1

Epitaxial growth was carried out in a vertical hot-wall reactor using Dichlorosilane (SiH₂Cl₂, DCS) and propane (C₃H₈) as precursors and H₂ as the carrier gas. The substrates were commercial 4H—SiC wafer with 4° offcut towards [11-20]. The growth temperature and pressure were 1600° C. and 80 Torr, respectively, with a C/Si ratio=1.42. The growth rate was 20 μm/hr and the doping concentrations were found to be from 5×10¹⁵cm⁻³ to 1×10¹⁶ cm⁻³ n-type for all the samples. After the first buffer layer growth, the sample was etched by a modified (MgO—KOH—NaOH) eutectic mixture. Etch pits of 5-7 μm in length measured along the [11-20] (step flow) direction were revealed at a temperature of 515° C. for 13-17 min etching time with good controllability and reproducibility. Recombination layers at different C/Si ratios (0.6 to 1.8) were subsequently grown on the eutectic etched samples. After this growth, the recombination layer was etched again by KOH etching at 550° C. to obtain etch pits of 10 μm size to examine the defect evolution. Since the recombination layer was used only to observe the defect conversion and not to preserve surface roughness, it was etched by traditional KOH etching method. The defects were observed using Nomarski optical microscopy (NOM) at the same surface locations on both epilayers. Atomic force microscopy (AFM, Digital Instruments Dimension 3100, tapping mode) was employed to study the surface morphology and shape of the BPD etch pits. The thickness of the epilayers were measured using the Fourier transform infrared reflectance (FTIR).²⁷ Net doping concentrations of the epilayers were measured by mercury probe Capacitance-Voltage method.^{∞}

### Buffer Epilayer Growth and Eutectic Etch for Revealing Basal Plane Dislocations

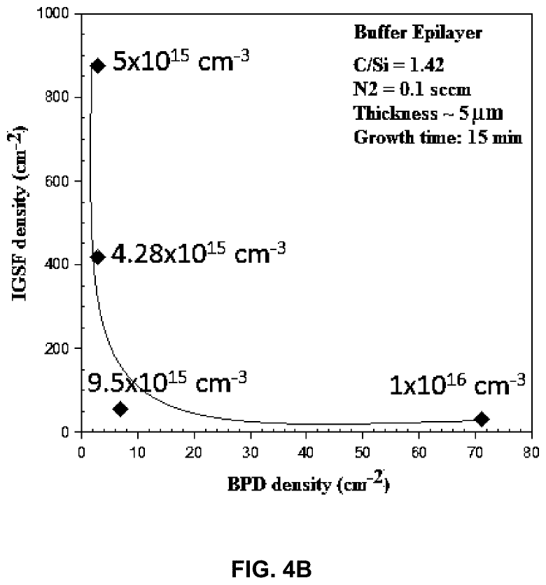

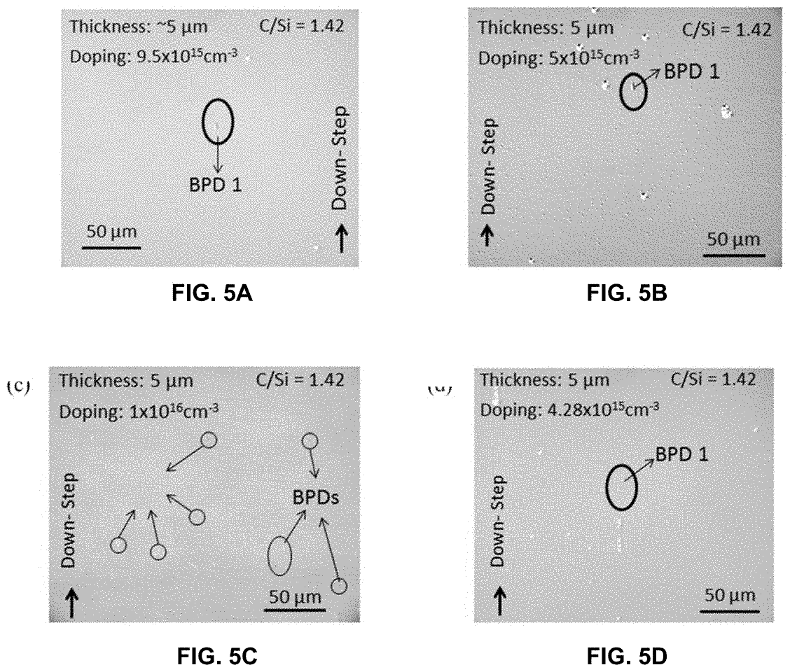

FIG. 4A shows the specific on-resistance and FIG. 4B shows the BPD and IGSF densities calculated after the first epilayer growth for a growth duration of 15 min at a fixed C/Si ratio=1.42 with 0.1 sccm intentional N₂ flow to obtain n-doping concentration in the epilayers. Nomarski images of these buffer epilayers are shown in FIG. 5A-FIG. 5D. All of the epilayers in FIG. 5A-FIG. 5D showed a similar thickness of 5 C/Si ratio of 1.42 was chosen for the first buffer epilayer growth as it is the best condition to obtain specular surface morphology with minimum BPD propagation on the buffer epilayer at a reasonable growth rate 20 μm/hr.²⁹ By intentionally adding less N₂ (0.1 sccm) at this condition, a net doping concentration ranging between (5×10¹⁵ cm⁻³ to 1×10¹⁶ cm⁻³) with a specific on-resistance <0.9 mΩ/cm² (FIG. 4A) was obtained for all the samples and this also helped the etching to occur faster (<15 min) due to the low doping concentration compared to the substrate.

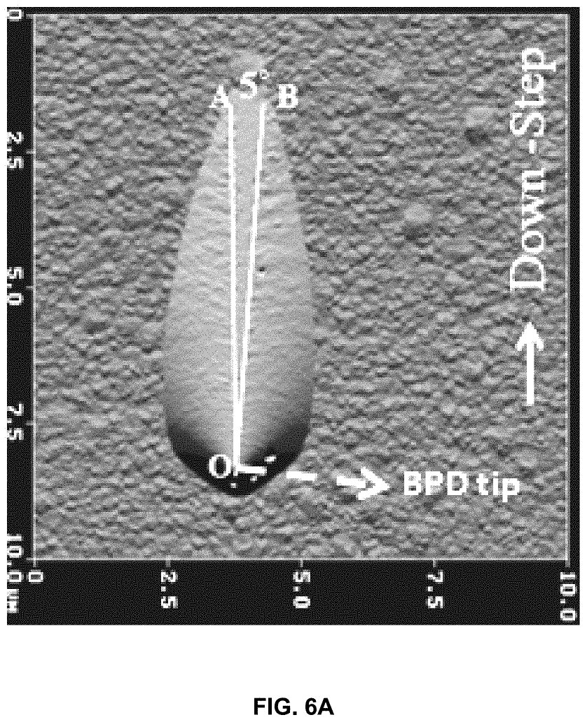

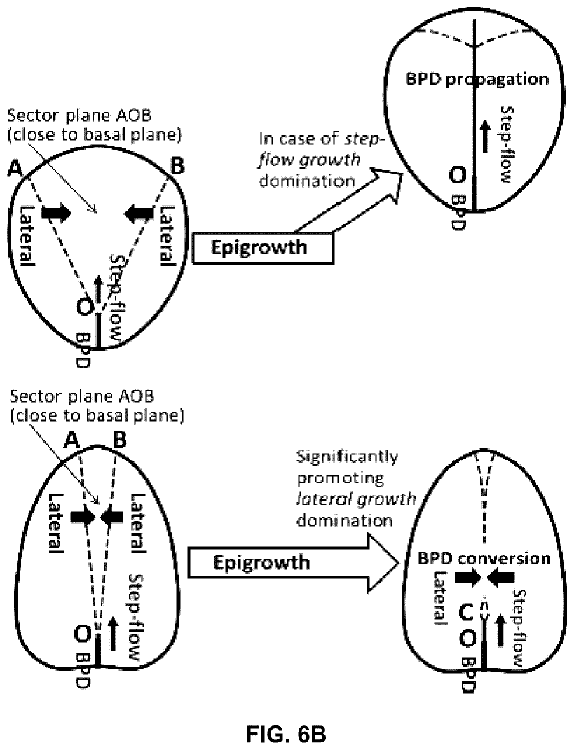

FIG. 5A-FIG. 5D show typical etch pits on the first buffer epilayers from eutectic etching. The threading screw dislocations (TSDs) have large hexagonal etch pits with a tip (lowest position within the etch pit) at the down-step side; TEDs have smaller hexagonal pits with a tip at the down-step side, and BPDs are shell-like shaped with a tip at the up-step side (FIG. 6A). All the epilayers (FIG. 5A-FIG. 5D) were etched for a duration ranging from 10 minutes to 13 minutes. The surface roughness of the first buffer epilayers had nearly no change before and after the eutectic etching (˜0.5 nm RMS change observed from AFM), thus preserving the epilayer surface morphology for the subsequent growth.

AFM scanning was done on the BPD etch pits seen on the eutectically etched epilayers. All the epilayers showed similar BPD structures with very narrow sector angle) (4.5°˜5° calculated from the sector shaped (angle AOB in FIG. 6A) basal plane (0001) exposed after the controlled and anisotropic eutectic etching. As schematically illustrated in FIG. 6B, the narrow opening of the sector plane enables lateral growth in the BPD and converts it into a TED at the interface during the subsequent recombination layer growth.¹³

### Recombination Layer Regrowth

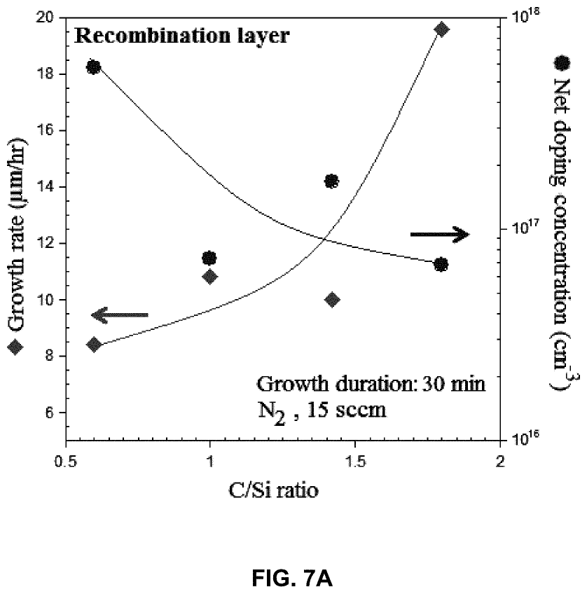

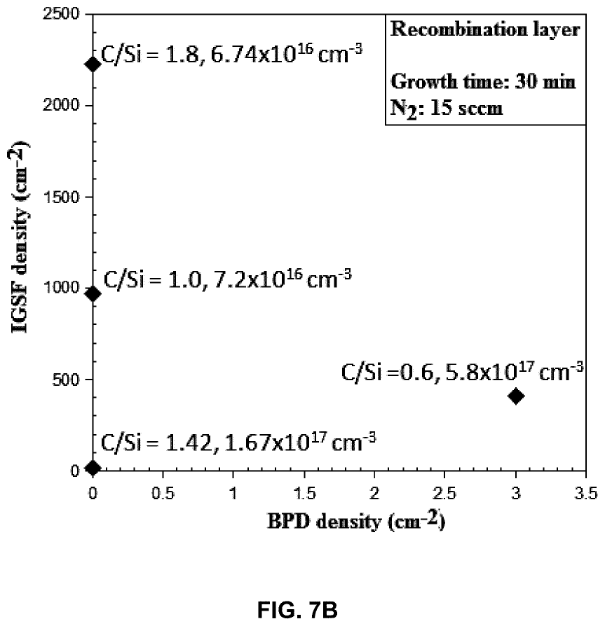

The etched buffer layers, after mapping of the delineated defects, were subjected to regrowth at different C/Si ratios from 0.6 to 1.8 by changing the flow rate of propane while keeping the flow of DCS constant. N₂ flow was increased to 15 sccm for the recombination layer growth in order to obtain higher doping concentration of the epilayers as well as to examine the influence of intentional doping on BPD conversion. The growth duration was increased to 30 min to produce thicker recombination layers. From FIG. 7A, the growth rate is observed increasing and the net doping concentration reduces with the increase in C/Si ratio, which is in accordance to previously reported results with DCS.²⁹

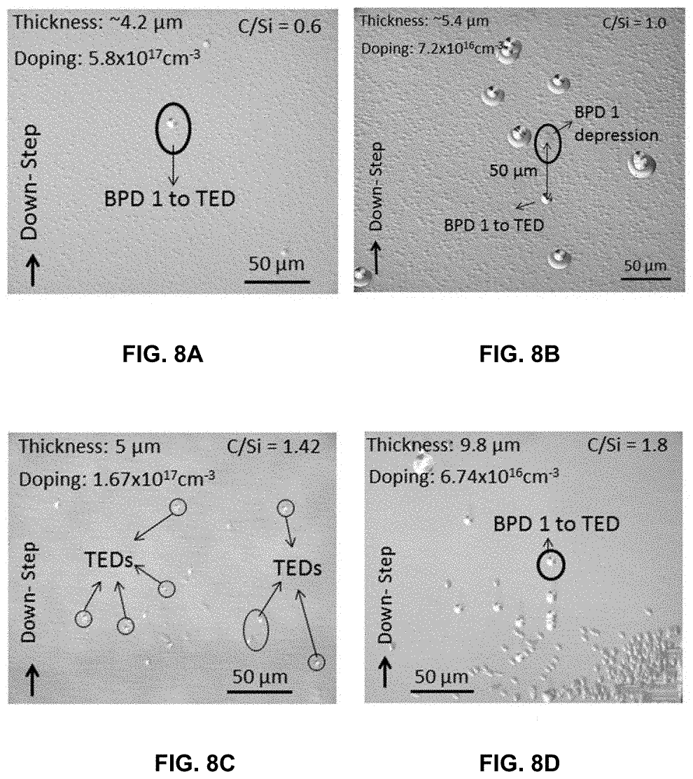

Following formation of the recombination layers, the recombination layers were KOH etched to reveal the defects on the epilayer surface, as shown in FIG. 8A-FIG. 8D. The Nomarski images shown in FIG. 8A-FIG. 8D were taken at positions where there were previously BPDs on the buffer epilayers (shown in FIG. 5A-FIG. 5D) and indicate the location of the converted TEDs on the corresponding recombination layers after regrowth. All the epilayers showed 100% BPD to TED conversion rate from the buffer layer with the only exception at C/Si=0.6.

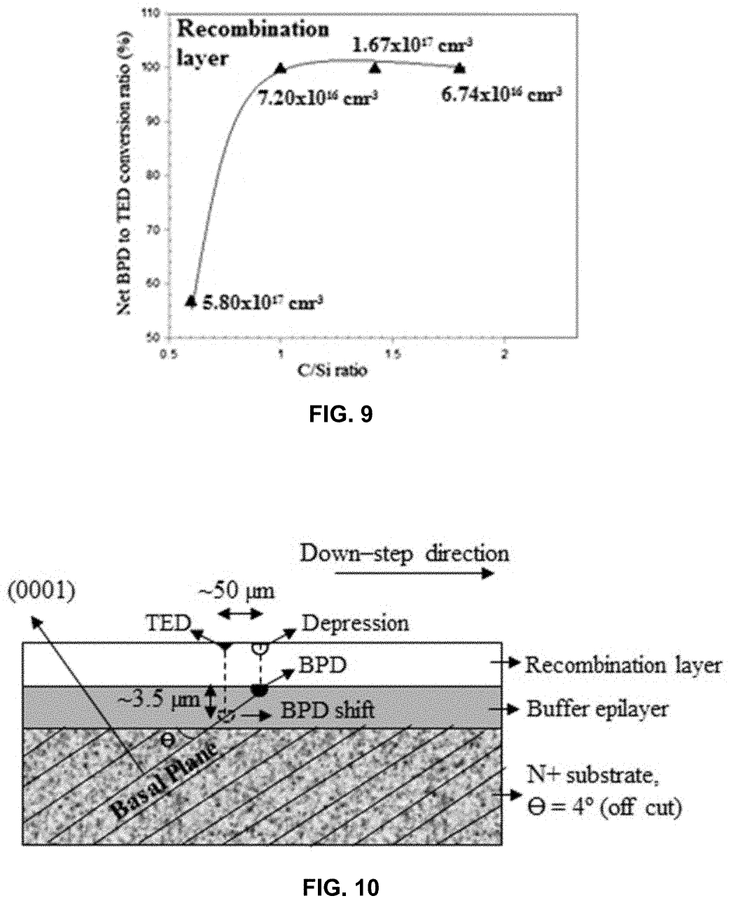

At C/Si=0.6, although all the BPDs from the buffer epilayer were converted into TEDs at the buffer-recombination layer interface, a new BPD was generated during the recombination layer growth, thus reducing the net BPD conversion ratio rate (FIG. 9). This is similar to the observations of V. D.Wheeler et al.⁴ in which it is reported that an abrupt increase in BPDs is reported at high nitrogen concentrations.

The reason for the formation of a new BPD on the recombination layer at C/Si=0.6 is due to the fact that the difference in the doping between the buffer layer and recombination layer is maximum at C/Si=0.6. The high N doping concentration of the recombination layer compared to the low doping in the buffer layer induces strain in the recombination layer. A threading dislocation segment in the buffer epilayer experiences a force due to the lattice misfit which is balanced by dislocation line tension. If the misfit induced force exceeds the force due to dislocation line tension, formation of a misfit dislocation is favorable.³⁰ Ohtani et al.³¹ have reported that nitrogen doping in the epilayer at high concentrations causes the epilayer step trains to become unstable: the equidistant step trains are transformed into meandering macrosteps by nitrogen adsorption on the growing crystal surface. The step flow growth balance between micro (vertical) and macrosteps (lateral growth) become unstable, and this phenomenon is said to exert more force on the dislocation line leading to the formation of a new BPD in the high-doped (˜5.8×10¹⁷ cm⁻³) recombination layer.

Another interesting result was observed at C/S ratio 1.0, where the BPD intersecting the etched buffer epilayer surface converts into a TED in the recombination layer, but the conversion point is not at the buffer-recombination layer interface. The BPD-TED conversion point is shifted by a certain distance along the up-step direction (see, e.g., FIG. 8B) which is referred to as a ‘TED glide.’ ³² This TED glide indicates that the BPD to TED conversion point is located beneath the buffer-recombination layer interface. The glide distance (˜50 μm measured from NOM) which when multiplied with the offcut (50 μm×tan))(4° comes to 3.5 μm. This implies that the BPD conversion point is shifted 3.5 μm below the buffer epilayer interface along the dislocation line (FIG. 10). The TED glide also indicates a decrease in the total dislocation energy by decreasing the dislocation line length.

As reported by Abadier et al.³², the above TED glide mechanism occurs in steps as follows: the BPD glides along the basal plane and its dislocation line aligns with the [11-20] direction. This causes the BPD partials to constrict and the constricted BPD gets converted into a local screw dislocation.³³ As a consequence, the local screw dislocation emerges as a TED which is pulled by its line tension and glides towards the up-step direction. The shift due to this TED glide is always towards the up-step direction.³²

For all other recombination layers grown at different C/Si ratios, the conversion point was at the interface of the buffer-recombination layer. This is identified by the location of the BPD depression on the buffer epilayer overlapping with the TED conversion point seen on recombination layer after KOH etching.

An ideal growth condition for 100% BPD conversion and minimum IGSF density was observed when the C/Si ratio was maintained the same for both the first buffer and the second recombination layers (FIG. 7B). The doping difference between two epilayers at this condition was found to be the minimum.³⁴ This plays an important role in minimizing the IGSF formation on the recombination layer as doping induced lattice misfits are the common reason for the formation of stacking faults in the epilayer due to their low energy of formation.^{30,35}

Since the doping difference was less and C/Si ratio was maintained the same (C/Si=1.42) on both epilayers, the surface step morphology was able to be preserved on both the epilayers. The effect of the growth morphology on the BPD conversion efficiency implies that the step structure around the emergence point of the BPD plays an important role in the conversion.³⁷ By maintaining the same C/Si=1.42 for the buffer and recombination layers, the step roughness and step bunching was preserved for both the epilayers and an ideal condition for growing BPD free epilayer with minimum IGSF density was achieved at this C/Si ratio.

In-grown stacking faults (IGSFs) observed on the buffer epilayer and the recombination layer show typical inverse relationship with the BPD density (FIG. 4B and FIG. 7B). In these results, the low doped buffer epilayer on the high doped substrate experiences compressive strain and the high doped recombination layer on the low doped buffer layer experienced tensile strain in the crystal lattice. Though the origin of IGSFs are not exactly known, doping concentration induced lattice misfit (strain) can also be a reason for some of these stacking faults.³⁰ The experimental reports of Huh et al.³⁵ and Jacobson et al.³⁷ suggest that the relaxation of homoepitaxial layers is linked to the formation of stacking faults. This is very likely due to the low stacking fault energy in 4H—SiC of 3-15 mJ/m².³⁸ Jacobson et al.³⁷ have shown that stacking faults occur in low N-doped epilayers (˜3×10¹⁵ cm⁻³) grown on highly N-doped substrates and they propagate up to 30 μm thickness. These results are consistent with results presented in this paper.

### Example 2

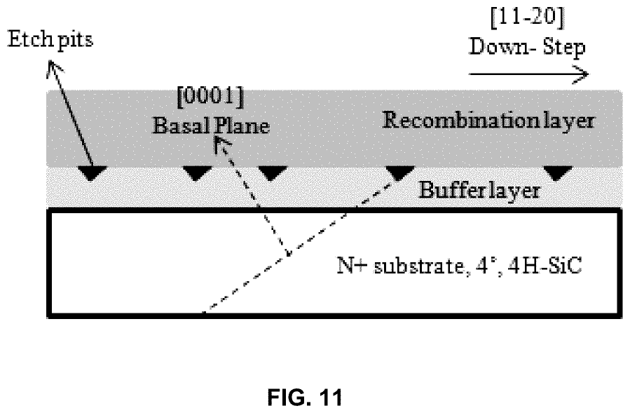

As schematically illustrated in FIG. 11, disclosed in one embodiment is an approach to pin the BPD to TED conversion point below the buffer layer interface. In this example, a low-doped n-type buffer epilayer (˜5 μm, 5×10¹⁵cm⁻³) was grown at C/Si ratio=1.4 by chemical vapor deposition (CVD) method and after growth, the epi/substrate was soaked in an optimized molten eutectic mixture (MgO+NaOH+KOH) in a nickel crucible at 515° C. to etch the buffer epilayer. The etched buffer epilayer was then subjected to regular RCA cleaning process prior to a regrowth (second epilayer) at C/Si=1.0 to serve as the recombination layer at high n-type doping concentration (5.4 μm, 7.2×10¹⁶cm⁻³). An MgO—KOH—NaOH eutectic mixture was employed to expose the defects on the n-buffer epilayer to create the etch pits in a well-controlled manner without surface degradation¹⁹.

The substrate was a commercially obtained 4H—SiC wafer with 4° off-axis towards direction and both Si and C faces chemical mechanical polished. Epilayer growths were carried out in a home-built chimney CVD reactor at 1600° C. and 80 Torr, using propane and dichlorosilane as precursors. The thickness of the buffer epilayer was ˜5 μm at C/Si=1.4 and ˜5.4 μm for the recombination layer at C/Si=1.0. The doping of the buffer, as well as the recombination layer, was n-type, controlled by C/Si ratios and N₂ addition. After buffer layer growth all the samples were etched by a molten eutectic melt to delineate defects and expose the etch pits on the epilayer. After the recombination layer growth, the same samples were etched either by the eutectic or KOH to examine the defects on the epilayers for BPD to TED conversion.

Mercury probe capacitance-voltage technique was used to measure the doping concentration and Fourier Transform Infrared Spectroscopy (FTIR) was used to measure the thicknesses of the buffer and recombination layers. Atomic Force Microscopy was used to measure the surface roughness each after growth and for imaging the BPD etch pits in the buffer layers after eutectic etching.

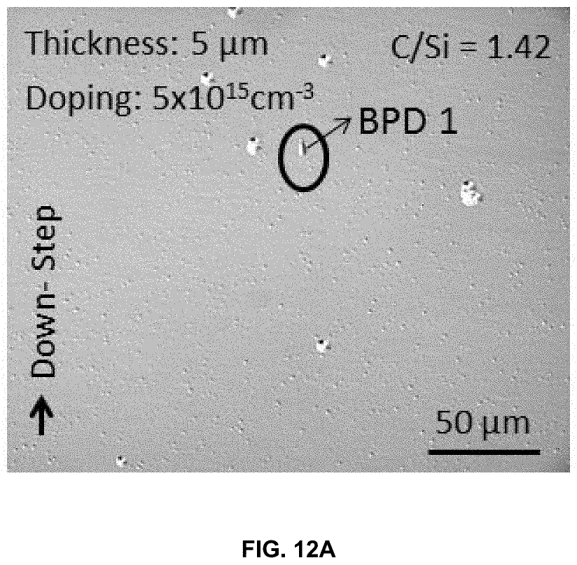

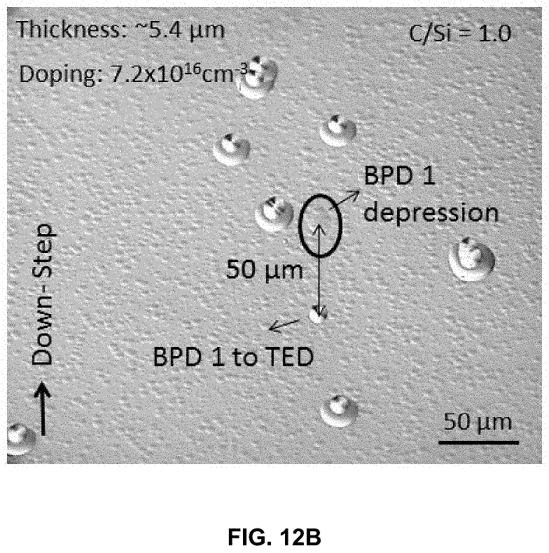

FIG. 12A shows the optical microscopy image of a BPD etch pit after eutectic etching of the buffer epilayer for 8 minutes in molten MgO+NaOH+KOH mixture at 515° C. The buffer epilayer growth condition was chosen to be at C/Si=1.4 to achieve maximum spontaneous BPD to TED conversion (without any additional growth processing steps such as etching, annealing or interrupts) based on previous experimental results in the specific growth reactor.²⁰ This buffer growth condition provided the least BPD density of 3 cm⁻² (only one BPD in an area of 6×6 mm²) to facilitate 100% BPD to TED conversion in the subsequent recombination layer growth.

This eutectically etched buffer epilayer, after defect characterization using optical microscopy and AFM, was subjected to regular RCA cleaning process for a regrowth (recombination layer growth) at C/Si=1.0. The recombination layer growth was tried for a range of C/Si from 0.6 to 1.8 to find out the C/Si influence on 100% BPD conversion while maintaining the same condition for buffer epilayer for all the growths. The recombination layers after growth were subjected to KOH etching to examine the conversion of BPDs to TEDs and to identify any newly generated BPDs on the recombination layers.

From KOH etching of the recombination layer grown at C/Si=1.0, it was found that the BPD intersecting the etched buffer epilayer surface (BPD1 in FIG. 12A) converted into a TED in the recombination layer (FIG. 12B), but the conversion point was not at the buffer epilayer interface. The BPD-TED conversion point was shifted (dragged back) by a certain distance along the up-step direction (FIG. 12B) which is referred to as a ‘TED glide.’²¹ This TED glide indicates that the BPD to TED conversion point was located beneath the buffer/recombination layer interface (FIG. 10). The glide distance was 50 μm measured from NOM optical microscope (FIG. 12B) which, when multiplied with the offcut (50 μm×tan (4°)), came to ˜3.5. This implies that the BPD conversion point was shifted 3.5 μm below the buffer/recombination epilayer interface (FIG. 10). The TED glide also indicates a decrease in the total dislocation energy by decreasing the dislocation line length.

The above TED glide mechanism occurs in steps as follows:²¹the BPD glides along the basal plane and its dislocation line aligns with the [11-20] direction. This causes the BPD partials to constrict and the constricted BPD gets converted into a local screw dislocation.²¹ As a consequence, the local screw dislocation emerges as a TED which is pulled by its line tension and glides towards the up-step direction. The shift due to this TED glide is always towards the up-step direction.²¹ For all the other recombination layers grown at different C/Si ratios the conversion point was at the buffer/recombination layer interface. This is identified by the location of the BPD depression created due to the etch pit in the buffer layer overlapping with the converted TED seen on recombination layer after etching.

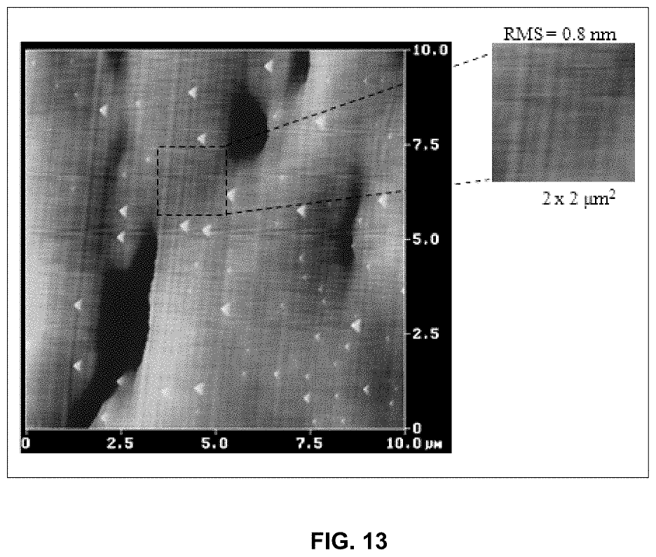

The reason for the BPD to TED conversion point shift at this particular growth condition (C/Si ratio) was mainly due to the net nitrogen impurity incorporation which strongly influenced the step dynamics of the recombination layer²², as shown in FIG. 9. It has been reported that the BPD to TED conversion is highly dependent on the step height and terrace width (step bunching) in an off oriented surface²³. Ha et a1²³ reported that the step structure of growth surface depends on the growth parameters such as off-cut angle and direction, surface polarity, growth rate, and C/Si ratio. In this experiment, only the C/Si ratio was varied, which in turn influenced the surface step morphology (step bunching) of the recombination layer. The effect of a stepped surface on the dislocation conversion will depend on the distance within which the image force can bend a dislocation. The average step height measured from the AFM (FIG. 13) was about 0.8 nm for the recombination layer (at C/Si=1.0) which is about 3/4th of a unit cell height of 4H—SiC (˜1 nm) and the terrace width was 156 nm. For the recombination layer at C/Si=1.4, the step height was about 6 nm and the terrace width was 234 nm due to pronounced step bunching at C-rich condition.²⁴ Without wishing to be bound by any particular theory, it is postulated that the kinks developed at these step edges influenced the image force to lower the dislocation line tension along the basal plane of the BPD etch pit and started to convert into a TED below the buffer/recombination layer interface.

Therefore, the composite growth technique including growing the buffer epilayer at C/Si=1.4 with a n-type doping 5×10¹⁵cm⁻³ and treating it in molten MgO—KOH—NaOH eutectic followed by a recombination layer growth at C/Si=1.0, was found to be a reliable, non-destructive and highly efficient way to eliminate BPDs and pin the conversion point below the epilayer interface.

In this example, the recombination layer growth was carried out at different C/Si ratios (0.6, 1.4, 1.8) other than C/Si=1.0 to understand and examine the influence of C/Si ratio on BPD conversion. Only the C/Si ratio of the recombination layer was varied keeping all the other growth conditions (growth duration, pressure, temperature, N₂ addition, buffer layer conditions) constant. The results obtained are explained as follows:

i) At C/Si=0.6, although all the BPDs from the first buffer layer were converted at the epilayer interface into TEDs on the recombination layer, a new BPD was generated during the recombination layer growth thus reducing the net BPD conversion ratio rate (FIG. 9). This is similar to the observations of V. D.Wheeler et al.² in which it is reported that an abrupt increase in BPDs is reported at high nitrogen concentrations (>10¹⁶ cm⁻³), which is 5.8×10¹⁷ cm⁻³ in this case. For the C/Si ratio range reported here, the difference in the net doping concentration between the buffer layer and recombination layer is maximum at C/Si=0.6. This high N doping concentration induces strain in the recombination layer. A threading dislocation segment in the first epilayer experiences a force due to the lattice misfit that exceeds the force due to dislocation line tension leading to the formation of a misfit dislocation (BPD).²⁵ Ohtani et al.²² have reported that nitrogen doping in the epilayer at high concentrations causes the epilayer step trains to become unstable the equidistant step trains are transformed into meandering macrosteps by nitrogen adsorption on the growing crystal surface. The step flow growth balance between micro (vertical) and macrosteps (lateral growth) become unstable and this phenomenon is said to exert more force on the dislocation line leading to the formation of a new BPD in the high-doped (˜5.8×10¹⁷ cm⁻³) recombination layer.

ii) At C/Si=1.4, 100% BPD conversion was achieved with the conversion point at the buffer/recombination layer interface. At this growth condition, and the recombination layer's C/Si ratio matches with the buffer layer C/Si ratio and hence the net doping difference between the two epilayers was found to be the least. The effect of the growth morphology on the BPD conversion efficiency implies that the step structure around the emergence point of the BPD plays an important role in the conversion.²⁶ The recombination layer at this C/Si ratio exhibited an average step height of 6 nm and the terrace width was 234 nm due to pronounced step bunching at C rich growth condition.²⁴

iii) At C/Si=1.8, 100% BPD conversion was achieved on the recombination layer with the conversion point at the interface of buffer/recombination layers. As expected at high C/Si ratio, the least net n-type doping concentration was obtained for the recombination layer due to the site competition epitaxy.²⁷ Interestingly, no effect due to the site competition was observed on the BPD conversion ratio at this high C growth condition. The recombination layer showed step bunching similar to the epilayer at C/Si=1.4, thus maintaining the BPD to TED conversion point at the buffer/recombination layer interface.

Though 100% BPD conversion was achieved for C/Si=1.0, 1.4 and 1.8, at ratios 1.4 and 1.8, the BPDs were converted at the interface of buffer/recombination layer due to more pronounced step bunching phenomenon seen at high C/Si ratios. But at C/Si=1.0, very minimal step bunching was observed at the recombination layer surface and consequently, a shift in the conversion point below the buffer/recombination layer which is ideal for fabricating robust/reliable high power, high voltage bipolar and unipolar devices.

These and other modifications and variations to the present invention may be practiced by those of ordinary skill in the art, without departing from the spirit and scope of the present invention, which is more particularly set forth in the appended claims. In addition, it should be understood that the aspects of the various embodiments may be interchanged both in whole or in part. Furthermore, those of ordinary skill in the art will appreciate that the foregoing description is by way of example only, and is not intended to limit the invention so further described in the appended claims.

### REFERENCES

1. Baliga, B. J. Introduction. Fundamentals of Power Semiconductor Devices; Springer Science and Business Media: New York, 2008; pp 1-20.

2. Konstantinov, A. O.; et al. Ionization rates and critical fields in 4H silicon carbide. Appl. Phys. Lett. 1997, 71, 90-92

3. Ryu, S. H.; et al. 1800 V NPN bipolar junction transistors in 4H—SiC. IEEE Electron Device Lett. 2001, 22(3), 124-126.

4. Wheeler, V. D.; et al. Effects of Nitrogen Doping on Basal Plane Dislocation Reduction in 8° Off-Cut 4H—SiC Epilayers. Mater. Sci. Forum. 2011, 679, 63-66.

5. Zhang, Z.; et al. Basal plane dislocation-free epitaxy of silicon carbide. Appl. Phys. Lett. 2005, 87(15), 151913.

6. Myers-Ward, Rachael L., et al. “Turning of basal plane dislocations during epitaxial growth on 4 off-axis 4H—SiC.” Mater. Sci. Forum. Vol. 615. pp. 105-108 Trans Tech Publications, 2009.

7. Ohno, T.; et al. Influence of growth conditions on basal plane dislocation in 4H—SiC epitaxial layer. J. Cryst. Growth. 2004, 271, 1-7

8. Klapper, H. T.; et al. Directions of dislocation lines in crystals of ammonium hydrogen oxalate hemihydrate grown from solution. Acta Crystallogr., Sect. A: Crystal Physics, Diffraction, Theoretical and General Crystallography. 1973, 29(5), 495-503.

9. Zhang, Z.; et al. Evolution of basal plane dislocations during 4H-silicon carbide homoepitaxy. Appl. Phys. Lett. 2005, 87, 161917.

10. Balachandran, A.; et al. 4H—SiC homoepitaxy on nearly on-axis substrates using TFS-towards high quality epitaxial growth. J. Cryst. Growth. 2016, 448, 97-104.

11. Chen, W.; et al. Growth and characterization of 4H—SiC epilayers on substrates with different off-cut angles. J. Appl. Phys. 2005, 98(11), 114907.

12. Sumakeris, Joseph J.; et al. Techniques for minimizing the basal plane dislocation density in SiC epilayers to reduce Vf drift in SiC bipolar power devices. Mater. Sci. Forum. 2006, 527-529, 141-146.

13. Song, H.; et al. Basal plane dislocation conversion near the epilayer/substrate interface in epitaxial growth of 4° off-axis 4H—SiC. J Cryst. Growth. 2013, 371, 94-101.

14. Zhang, X.; et al. Conversion of basal plane dislocations to threading edge dislocations in 4H—SiC epilayers by high temperature annealing. J. Appl. Phys. 2012, 111(12), 123512.

15. Mahadik, N. A.; et al. Mitigation of BPD by Pre-Epigrowth High Temperature Substrate Annealing. Mater. Sci. Forum. 2016, 858, 233-236.

16. Sun, Y.; et al. Reduction of epitaxial defects on 4°-off 4H—SiC homo-epitaxial growth by optimizing in-situ etching process. Superlattices and Microstructures. 2016.

17. VanMil, B. L.; et al. Basal plane dislocation reduction for 8 off-cut, 4H—SiC using in situ variable temperature growth interruptions. J. Vac. Sci. Technol. B. 2008, 26(4), 1504-1507.

18. Dow Corning. Dow Corning® Prime Grade 100 mm Silicon Carbide Wafers. 2014.

19. Mahadik, N. A.; et al. Observation of stacking faults from basal plane dislocations in highly doped 4H—SiC epilayers. Appl. Phys. Lett. 2012, 100(4), 042102.

20. VanMil, B. L., et al. Etch rates near hot-wall CVD growth temperature for Si-face 4H—SiC using H₂ and C₃H₈. Journal of Crystal Growth 311.2 (2009): 238-243.

21. Stahlbush, R. E., et al. Basal plane dislocation reduction in 4H—SiC epitaxy by growth interruptions. Applied Physics Letters 94.4 (2009): 041916.

22. Song, H., et al. Investigations of defect evolution and basal plane dislocation elimination in CVD epitaxial growth of silicon carbide on eutectic etched epilayers. Journal of Crystal Growth 320.1 (2011): 95-102.

23. Sakwe, S. A., et al. Optimization of KOH etching parameters for quantitative defect recognition in n-and p-type doped SiC. Journal of crystal growth 289.2 (2006): 520-526.

24. Sze, S. M. Carrier Transport and Phenomena. Semiconductor devices: Physics and Technology. John Wiley & Sons: New York, 2002; pp-61

25. Hatayama, T.; et al. Analysis of minority carrier diffusion length in SiC toward high quality epitaxial growth. Microelectron. Eng. 2006, 83(1), 30-33.

26. Schaffer, W. J.; et al. Conductivity Anisotropy in Epitaxial 6H and 4H SiC. Mater. Res. Soc. Symp. Proc. 1994, 339, 595.

27. S. Sunkari, M. S.; et al. Investigation of longitudinal-optical phonon-plasmon coupled modes in SiC epitaxial film using fourier transform infrared reflection. J. Electron. Mater. 2005, 34, 320-323

28. Kim, H. J.; et al. Theoretical and Empirical Studies of Impurity Incorporation into β-SiC Thin Films during Epitaxial Growth. J. Electrochem. Soc. 1986, 133(11), 2350-2357.

29. Song, H.; et al. Study of Surface Morphology, Impurity Incorporation and Defect Generation during Homoepitaxial Growth of 4H—SiC Using Dichlorosilane. ECS J. Solid State Sci. Technol. 2015, 4(3), 71-76.

30. Kallinger, B.; et al. Doping induced lattice misfit in 4H—SiC homoepitaxy. J. Cryst. Growth. 2012, 349(1), 43-49.

31. Ohtani, N.; et al. Evolution of macrosteps on 6H—SiC (0001): Impurity-induced morphological instability of step trains. Phys. Rev. B: Condens. Matter Mater. Phys. 1999, 59(7), 4592.

32. Abadier, M.; et al. Glide of threading edge dislocations after basal plane dislocation conversion during 4H—SiC epitaxial growth. J. Cryst. Growth. 2015, 418, 7-14.

33. Chung, S.; et al. Direct observation of basal-plane to threading-edge dislocation conversion in 4H—SiC epitaxy. J. Appl. Phys. 2011, 109(9), 094906.

34. Brillson, L. J.; et al. Thermal and doping dependence of 4H—SiC polytype transformation. Appl. Phys. Lett. 2002, 81(15), 2785-2787.

35. Huh, S. W.; et al. Doping-induced strain and relaxation of Al-doped 4H—SiC homoepitaxial layers. J. Appl. Phys. 2004, 96(8), 4637-4641.

36. Ha, S.; et al. Dislocation conversion in 4H silicon carbide epitaxy. J. Cryst. Growth. 2002, 244(3), 257-266.

37. Jacobson, H.; et al. Doping-induced strain in N-doped 4H-SiC crystals. Appl. Phys. Lett. 2003, 82(21), 3689-3691.

38. Hong, M. H.; et al. Stacking fault energy of 6H—SiC and 4H—SiC single crystals. Philos. Mag. 2000, 80(4), 919-935.

1. A method of growing a composite SiC epilayer structure, the method comprising:
growing a buffer layer on a surface of a SiC substrate, wherein the buffer layer comprises SiC;
applying a molten mixture directly onto the buffer layer to form a treated buffer layer; and
thereafter, growing a recombination layer on the treated buffer layer, wherein the recombination layer comprises SiC.

2. The method of claim 1, wherein the buffer layer is n-doped.

3. The method of claim 1, wherein the buffer layer has a dopant concentration of about 1×10¹⁶ cm⁻³ or less.

4. The method of claim 1, wherein the buffer layer has a thickness of about 0.5 μm to about 5 μm.

5. The method of claim 1, wherein the application of the molten mixture converts basal plane dislocations present on the buffer layer to threading edge dislocations.

6. The method of claim 1, wherein the recombination layer is n-doped.

7. The method of claim 3, wherein the recombination layer has a dopant concentration that is greater than the dopant concentration of the buffer layer.

8. The method of claim 4, wherein the recombination layer has a thickness that is greater than a thickness of the buffer layer.

9. The method of claim 1, wherein the recombination layer has a C/Si ratio of about 0.6 to about 1.8.

10. The method of claim 1, wherein the molten mixture comprises KOH and a buffering agent, the buffering agent being present in the molten mixture in an amount of about 5% to about 80% by weight.

11. The method as in claim 10, wherein the buffering agent comprises MgO.

12. The method of claim 1, wherein the molten mixture comprises KOH, a buffering agent, and at least one additional salt.

13. The method of claim 1, wherein the molten mixture comprises KOH and NaOHe in a KOH:NaOH weight ratio of about 1:4 to about 4:1.

14. (canceled)

15. The method of claim 1, wherein the molten mixture is applied to the buffer layer with the molten mixture at a temperature of about 170° C. to about 800° C. for a treatment duration that is from about 1 minute to about 60 minutes.

16. The method of claim 1, wherein buffer layer and the recombination layer are grown via chemical vapor deposition utilizing a Si-source gas and a carbon-source gas, wherein the Si-source gas and the carbon-source gas may be the same or different in the growth of the buffer layer and the growth of the recombination layer.

17. The method as in claim 16, wherein the Si-source gas and the carbon-source gas are provided during the growth of the buffer layer and the recombination layer independently at a molar ratio of C/Si from about 0.6 to about 1.8.

18. The method as in any preceding claim, wherein the composite SiC epilayer structure is not subjected to a post-polishing or a dry etching process following formation of the recombination layer.

19. The method of claim 1, further comprising fabrication of SiC unipolar or bipolar device on the recombination layer.

20. The method of claim 1, wherein the SiC substrate has a polytype selected from the 3C, 4H, 6H or I5R.

21. The method of claim 1, wherein the SiC substrate has an offcut angle ranging from 0.5° to 12°.

22. The method of claim 1, wherein the SiC substrate has a doping type selected from N+, N−, P+, P− and semi-insulating.

23. The method of claim 1, wherein the buffer layer and the recombination layer independently each have a doping concentration ranging from semi-insulating to about 10¹⁷ cm⁻³ or less.

24. The method of claim 1, wherein the recombination layer has a doping concentration of about 10¹⁷cm⁻³ or greater.

25. The method of claim 5, wherein the application of the molten mixture converts 100% of the basal plane dislocations present on the buffer layer to threading edge dislocations.
